(19) United States
(12) Patent Application Publication
(10) Pub. No.: US 2011/0234704 A1
(43) Pub. Date: Sep. 29, 2011

(54) PIEZOELECTRIC ELEMENT, PIEZOELECTRIC ACTUATOR, LIQUID DROPLET EJECTING HEAD, LIQUID DROPLET EJECTING APPARATUS, AND METHOD OF PRODUCING PIEZOELECTRIC ELEMENT

(75) Inventors: Hideki Hahiro, Shiojiri-shi (JP); Koji Ohashi, Matsumoto-shi (JP); Masao Nakayama, Shiojiri-shi (JP)

(73) Assignee: SEIKO EPSON CORPORATION, Shinjuku-ku (JP)

(21) Appl. No.: 13/069,343

(22) Filed: Mar. 22, 2011

(30) Foreign Application Priority Data
Mar. 23, 2010 (JP) 2010-065847

(51) Int. Cl. B41J 2/045; H01L 41/04; H01L 41/22

(52) U.S. Cl. 347/68; 310/340; 29/25.35

(57) ABSTRACT

The piezoelectric element includes a first electrode disposed on a substrate, a piezoelectric material layer disposed on the first electrode, a second electrode disposed on the piezoelectric material layer, and a protective film covering at least a side surface of the piezoelectric material layer. The side surface of the piezoelectric material layer has a plurality of grooves extending along the direction from the second electrode toward the first electrode.

This application claims a priority to Japanese Patent Application No. 2010-065847 filed on Mar. 23, 2010 which is hereby expressly incorporated by reference herein in its entirety.

### BACKGROUND

1. Technical Field

The present invention relates to a piezoelectric element, a piezoelectric actuator, a liquid droplet ejecting head, a liquid droplet ejecting apparatus, and a method of producing a piezoelectric element.

2. Related Art

In order to reduce the thicknesses of piezoelectric elements for enabling high-speed driving, it is known to produce piezoelectric actuators and ink jet recording heads by thin-film technology. For example, JP-A-10-226071 describes an ink jet recording head that can be produced by the thin-film technology.

In the ink jet recording head described in JP-A-10-226071, in order to solve the problems such as occurrence of leakage current between an upper electrode and a lower electrode through the side surface of a piezoelectric material layer of a piezoelectric element or deterioration of the piezoelectric material layer caused by moisture absorbed from the atmosphere, a protective film composed of an insulator layer is provided on the side surface of the piezoelectric material layer.

In order to improve the reliability of a piezoelectric element having such a structure, adhesion between the protective film and the side surface of the piezoelectric material layer is important. If the adhesion between the protective film and the piezoelectric material layer is insufficient, leakage current occurs due to a gap generated between the protective film and the piezoelectric material layer when the piezoelectric element is driven by application of a voltage, which may cause short circuit between the upper electrode and the lower electrode. Therefore, there is a demand for a piezoelectric element in which the adhesion between the protective film and the side surface of the piezoelectric material layer is further enhanced.

### SUMMARY

Advantages of some aspects of the invention are to provide a piezoelectric element having improved reliability by enhancing the adhesion between a protective film and a piezoelectric material layer; a method of producing the piezoelectric element; and a piezoelectric actuator, a liquid droplet ejecting head, and a liquid droplet ejecting apparatus that have the piezoelectric elements.

(1) The piezoelectric element according to an aspect of the invention includes a first electrode disposed on a substrate; a piezoelectric material layer disposed on the first electrode; a second electrode disposed on the piezoelectric material layer; and a protective film covering at least a side surface of the piezoelectric material layer, wherein the side surface of the piezoelectric material layer has a plurality of grooves extending along the direction from the second electrode toward the first electrode.

In the invention, the term “on” is used in, for example, that “a specific matter (hereinafter referred to as “B”) is disposed “on” another specific matter (hereinafter referred to as “A”). In the invention, in such a case, the term “on” includes the case in that B is disposed on A so as to be in contact with A and the case in that B is disposed over A with another matter therebetween. Similarly, the term “under” includes the case in that B is disposed under A so as to be in contact with A and the case in that B is disposed under A with another matter therebetween.

According to an aspect of the invention, the side surface of the piezoelectric material layer has a plurality of grooves extending along the direction from the second electrode toward the first electrode, and the protective film is formed on the side surface. By doing so, since surfaces adhering to the protective film are also formed in the grooves, the area where the protective film comes into contact with the piezoelectric material layer is increased, compared to the case in that the side surface of the piezoelectric material layer is substantially flat. Therefore, a piezoelectric element having improved adhesion between the protective film and the side surface of the piezoelectric material layer can be provided.

(2) In the piezoelectric element according to an aspect of the invention, the grooves on the side surface may each have a depth of 20 to 200 nm.

By doing so, the adhesion between the protective film and the side surface of the piezoelectric element can be reliably improved.

(3) In the piezoelectric element according to an aspect of the invention, the protective film may be made of an insulating resin material and/or an insulating inorganic material.

(4) The piezoelectric actuator according to an aspect of the invention includes any one of the above-described piezoelectric elements.

According to an aspect of the invention, a piezoelectric actuator having the piezoelectric element according to one aspect of the invention can be provided.

(5) The liquid droplet ejecting head according to an aspect of the invention includes the above-mentioned piezoelectric actuator.

According to an aspect of the invention, a liquid droplet ejecting head having the piezoelectric actuator according to an aspect of the invention can be provided.

(6) The liquid droplet ejecting apparatus according to an aspect of the invention includes the above-mentioned liquid droplet ejecting head.

According to an aspect of the invention, a liquid droplet ejecting apparatus having the liquid droplet ejecting head according to an aspect of the invention can be provided.

(7) The method of forming a piezoelectric element according to an aspect of the invention includes forming a first electrode on a substrate; forming a piezoelectric material film on the first electrode; forming a piezoelectric material layer by patterning the piezoelectric material film by dry etching; forming a second electrode on the piezoelectric material layer; and forming a protective film covering at least a side surface of the piezoelectric material layer, wherein the etching gas in the dry etching is a gas mixture whose main component is a chlorine-based gas containing BCl₃.

According to an aspect of the invention, a method producing the piezoelectric element according to an aspect of the invention can be provided.

(8) In the method of producing a piezoelectric element according to an aspect of the invention, the gas mixture may contain at least BCl₃ and C₄F₈ with a mixing ratio of BCl₃ to C₄F₈ in the range of 1 to 4.

(9) In the method of producing a piezoelectric element according to an aspect of the invention, the dry etching may be performed under a pressure of 1.0 Pa or less.

### BRIEF DESCRIPTION OF THE DRAWINGS

The invention will be described with reference to the accompanying drawings, wherein like numbers reference like elements.

FIG. 1A is a plan view schematically illustrating a piezoelectric element according to an embodiment.

FIG. 1B is a cross-sectional view of the piezoelectric element taken along the line IB-IB in FIG. 1A.

FIG. 2A is a perspective view schematically illustrating only a piezoelectric material layer of the piezoelectric element.

FIG. 2B is a cross-sectional view schematically illustrating the shape of a side surface of the piezoelectric material layer taken along the line IIB-IIB in FIG. 1B.

FIG. 3A is a cross-sectional view schematically showing a process of producing the piezoelectric element of an embodiment.

FIG. 3B is a cross-sectional view schematically showing the process of producing the piezoelectric element of the embodiment.

FIG. 3C is a cross-sectional view schematically showing the process of producing the piezoelectric element of the embodiment.

FIG. 3D is a cross-sectional view schematically showing the process of producing the piezoelectric element of the embodiment.

FIG. 4A is a cross-sectional view schematically showing the process of producing the piezoelectric element of the embodiment.

FIG. 4B is a cross-sectional view schematically showing the process of producing the piezoelectric element of the embodiment.

FIG. 5 is a cross-sectional view schematically illustrating the main portion of a liquid droplet ejecting head according to an embodiment.

FIG. 6 is an exploded perspective view of the liquid droplet ejecting head according to the embodiment.

FIG. 7 is a perspective view schematically illustrating a liquid droplet ejecting apparatus according to an embodiment.

FIG. 8A is an SEM image showing the surface state of a side surface of the piezoelectric material layer of a piezoelectric element according to an example.

FIG. 8B is an SEM image showing the surface state of a side surface of the piezoelectric material layer of a piezoelectric element according to a comparative example.

FIG. 9 is a graph showing the results of a withstand voltage test of the piezoelectric element according to the example and the piezoelectric element according to the comparative example.

### DESCRIPTION OF EXEMPLARY EMBODIMENTS

A preferred embodiment of the invention will be described in detail below with reference to the drawings. Note that the embodiments described below do not unduly limit the scope of the invention described in the claims. In addition, all of the compositions described below are not always essential constitutional requirements of the invention.

### 1. Piezoelectric Element and Piezoelectric Actuator

### 1-1. Structures of Piezoelectric Element and Piezoelectric Actuator

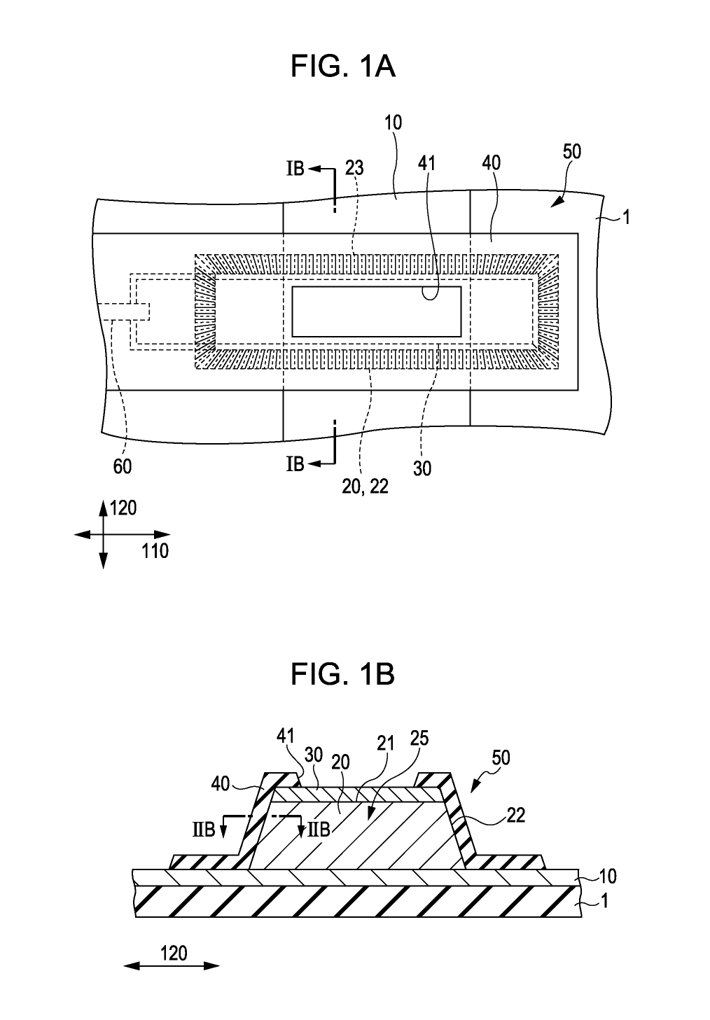

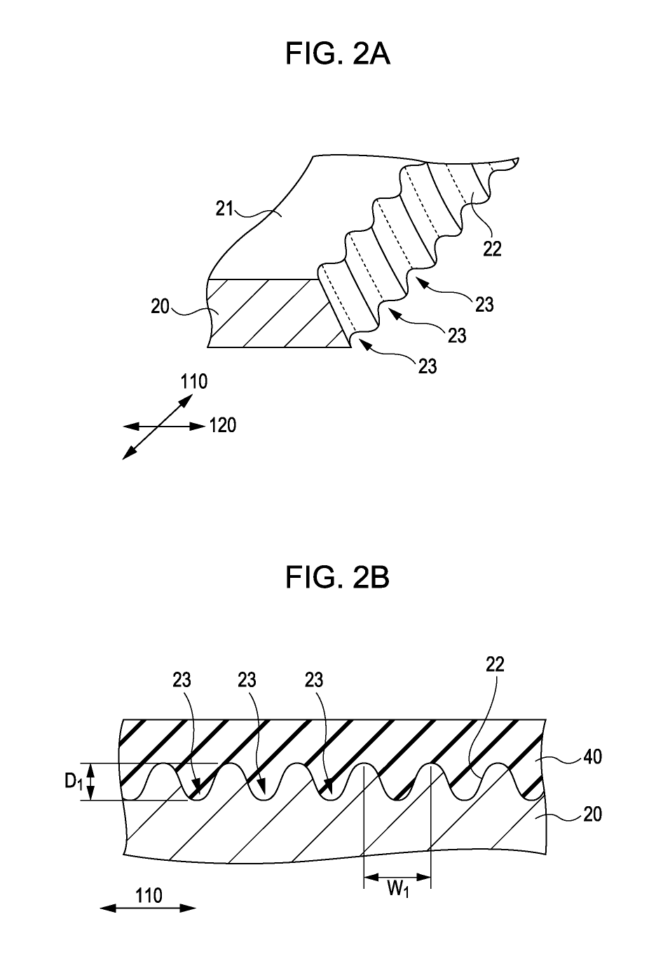

FIG. 1A is a plan view schematically illustrating a piezoelectric element according to an embodiment, and FIG. 1B is a cross-sectional view of the piezoelectric element taken along the line IB-IB in FIG. 1A. FIG. 2A is a perspective view schematically illustrating a side surface of a piezoelectric material layer of the piezoelectric element, and FIG. 2B is a cross-sectional view of the piezoelectric element taken along the line IIB-IIB in FIG. 1B and schematically illustrates a shape of the side surface of the piezoelectric material layer.

As shown in FIGS. 1A and 1B, the piezoelectric element 50 according to this embodiment includes a first electrode 10, a piezoelectric material layer 20, a second electrode 30, and a protective film 40.

As shown in FIG. 1A, the piezoelectric element 50 is formed on a substrate 1. As shown in FIG. 1A, the piezoelectric element 50 may be formed so as to extend in one direction. Here, the direction in which the piezoelectric element 50 extends is denoted as a first direction 110. As shown in FIGS. 1A and 1B, a direction crossing the first direction is denoted as a second direction 120. For example, the first direction 110 and the second direction 120 may be substantially orthogonal to each other.

The substrate 1 can be a flat plate formed of, for example, an electrically conductive, semiconductive, or insulative material. The substrate 1 may be a single layer or has a laminate structure composed of a plurality of layers. The structure of the inside of the substrate 1 is not limited as long as the upper surface has a planar shape. For example, the substrate 1 may have a structure in which space is formed inside the substrate 1.

When the substrate 1 serves as a diaphragm of a piezoelectric actuator including the piezoelectric element 50, it functions as a member that produces a mechanical output in operation of the piezoelectric element 50. The substrate 1 can be a movable portion of a piezoelectric actuator including the piezoelectric element 50 and may constitute part of the wall of, for example, a pressure-generating chamber. The thickness of the substrate 1 is optimized according to, for example, the modulus of elasticity of its material. When the substrate 1 is the diaphragm of a piezoelectric actuator including the piezoelectric element 50, the thickness of the substrate 1 can be, for example, 200 to 2000 nm. When the thickness of the substrate 1 is smaller than 200 nm, extraction of a mechanical output, such as vibration, may become difficult. When the thickness is larger than 2000 nm, for example, vibration may not occur. The substrate 1 can be deflected or vibrated by operation of the piezoelectric material layer 20.

When the substrate 1 is the diaphragm of a piezoelectric actuator including the piezoelectric element 50, the material for the substrate 1 preferably has high rigidity and mechanical strength. Examples of the material of the substrate 1 include inorganic oxides, such as zirconium oxide, silicon nitride, and silicon oxide, and alloys, such as stainless steel. Among them, zirconium oxide is preferred as the material for the substrate 1 from the viewpoint of chemical stability and rigidity. The substrate 1 may have a laminate structure composed of two or more the exemplified materials.

As shown FIGS. 1A and 1B, the first electrode 10 is disposed on the substrate 1. The region where the first electrode 10 is disposed is not particularly limited as long as it overlaps the piezoelectric material layer 20 and the second electrode 30 described below on the substrate 1. For example, as shown in FIGS. 1A and 1B, the first electrode 10 may extend in the second direction 120 so as not to be covered with the piezoelectric material layer 20.

The first electrode 10 forms a pair of electrodes with the second electrode 30 so as to have the piezoelectric material layer 20 therebetween. The first electrode 10 may be, for example, a lower electrode of the piezoelectric element 50. The first electrode 10 is electrically connected to lead wiring that is electrically connected to a driving circuit (not shown). The method for the electrical connection between the first electrode 10 and the lead wiring is not particularly limited.

The material for the first electrode 10 is not particularly limited as long as it has electrical conductivity. Examples of the material for the first electrode 10 include various metals, such as Ni, Ir, Au, Pt, W, Ti, Ta, Mo, and Cr, and alloys of these metals, and electrically conductive oxides thereof (e.g., iridium oxide), complex oxides of Sr and Ru, and complex oxides of La and Ni. Furthermore, the first electrode 10 may be a single layer of the exemplified material or have a laminate structure composed of a plurality of materials.

As shown in FIGS. 1A and 1B, the piezoelectric material layer 20 is disposed between the first electrode 10 and the second electrode 30. As shown in FIGS. 1A and 1B, at least part of the piezoelectric material layer 20 is arranged on the first electrode 10. As shown in FIG. 1A, the piezoelectric material layer 20 may be formed so as to extend in the first direction 110. As shown in FIG. 1B, the piezoelectric material layer 20 has an upper surface 21 (the surface on the side opposite to the first electrode 10 side) on which the second electrode 30 is formed, which is described below, and a tapered side surface 22. The side surface 22 is a continuous surface connecting the surface on the first electrode 10 side and the upper surface 21. As shown in FIG. 1A, the side surface 22 has a plurality of grooves 23 extending along the direction from the second electrode 30 toward the first electrode 10. The details thereof will be described below. The thickness of the piezoelectric material layer 20 is not particularly limited as long as it can be substantially deformed, that is, can be expanded and contracted, when a voltage is applied.

A preferred material for the piezoelectric material layer 20 is a perovskite oxide shown by a general formula, ABO₃. Examples of such a material include lead zirconate titanate (Pb(Zr,Ti)O₃) (hereinafter may be abbreviated to “PZT” in the specification), lead zirconate titanate niobate (Pb(Zr,Ti,Nb)O₃) (hereinafter may be abbreviated to “PZTN” in the specification), barium titanate (BaTiO₃), and potassium sodium niobate ((K,Na)NbO₃).

The second electrode 30 is arranged on the piezoelectric material layer 20 so as to oppose the first electrode 10. In the example shown in FIG. 1B, the second electrode 30 is disposed on the piezoelectric material layer 20. The region where the second electrode 30 is disposed is not particularly limited as long as the second electrode 30 is disposed on the piezoelectric material layer 20, overlaps at least part of the first electrode 10, and forms a driving region 25 (which is a region of the piezoelectric material layer 20 between the first electrode 10 and the second electrode 30 and substantially deforms), as shown in FIG. 1B. Therefore, the detailed shape of the second electrode 30 is designed when the driving region is determined and can be appropriately determined according to a desired driving region.

The second electrode 30 forms a pair of electrodes with the first electrode 10 so as to have the piezoelectric material layer 20 therebetween. When the first electrode 10 is the lower electrode, the second electrode 30 may be the upper electrode. The second electrode 30 is electrically connected to a driving circuit (not shown). The method for the electrical connection between the second electrode 30 and the driving circuit is not particularly limited. The second electrode 30 and the driving circuit may be electrically connected, for example, via lead wiring 60, as shown in FIG. 1A.

The material of the second electrode 30 is not particularly limited as long as it has electrical conductivity. Examples of the material for the second electrode 30 include various metals, such as Ni, Ir, Au, Pt, W, Ti, Ta, Mo, and Cr, and alloys of these metals, and electrically conductive oxides thereof (e.g., iridium oxide), complex oxides of Sr and Ru, and complex oxides of La and Ni. Furthermore, the second electrode 30 may be a single layer of the exemplified material or have a laminate structure composed of a plurality of the materials.

As shown in FIGS. 1A and 1B, the protective film 40 is formed so as to cover at least the side surface 22 of the piezoelectric material layer 20. The shape of the protective film 40 is not particularly limited as long as it covers at least the side surface 22 of the piezoelectric material layer 20. As shown in FIG. 1A, the protective film 40 may have an opening 41 opened to expose at least part of the second electrode 30 above the driving region 25 of the piezoelectric material layer 20. As shown in FIGS. 1A and 1B, the protective film 40 may continuously cover part of the first electrode 10, the side surface 22 of the piezoelectric material layer 20, and part of the second electrode 30. Furthermore, as shown in FIG. 1A, the protective film 40 may continuously cover a portion where the second electrode 30 and the lead wiring 60 are electrically connected to each other.

The material of the protective film 40 is not particularly limited as long as it has an insulating property. For example, the protective film 40 can be formed using a known insulating resin material or insulating inorganic material.

The known insulating resin material may be, for example, a known photosensitive resin material or non-photosensitive resin material. When the insulating resin material is a photosensitive resin material, for example, known unsaturated-bond-containing polymerizable compound and photopolymerization initiator may be further contained. Specifically, the insulating resin material may be a photoresist or a resin composition of polyimide, benzocyclobutene (BCB), a polyvinyl alcohol derivative, or the like.

The term “photosensitivity” of the photosensitive material in the invention refers to characteristics capable of selectively removing a specific region by selectively exposing the region to energy rays, such as radiation, and subjecting the region to development with a developer. Therefore, for example, the photosensitive material may be a positive resist in which the portion of the resist that is exposed to energy rays, such as radiation, can be selectively removed by a developer or may be a negative resist in which the unexposed portion of the resist can be selectively removed by a developer.

The known insulating inorganic material may be aluminum oxide or silicon oxide.

The piezoelectric material layer 20 according to this embodiment will be described in detail below with reference to FIGS. 2A and 2B.

As shown in FIG. 2A, the side surface 22 of the piezoelectric material layer 20 has a plurality of grooves 23 extending along the direction from the second electrode 30 toward the first electrode 10 (direction from the top to the bottom of the taper surface). The grooves 23 may be partially formed on the side surface 22 near the region that is substantially driven (not shown).

In this embodiment, the direction from the second electrode 30 toward the first electrode 10 (direction from the top to the bottom of the taper surface) is a substantially straight direction, on the side surface 22 being a tapered slant surface (surface that is not perpendicular to the substrate 1), from the boundary line between the side surface 22 and the upper surface 21 toward the boundary line between the side surface 22 and the first electrode 10 (or the substrate 1). For example, the direction from the second electrode 30 toward the first electrode 10 may be the perpendicular direction from the boundary line between the side surface 22 and the upper surface 21 toward the boundary line between the side surface 22 and the first electrode 10 (or the substrate 1).

In this embodiment, the grooves 23 are sequentially formed in one direction. That is, the grooves 23 refer to portions substantially concaved toward the inside of the piezoelectric material layer 20, compared to the top surface of the side surface 22. In this meaning, the grooves 23 in this embodiment differ from dents not having directivity in the region where they are formed.

As shown in FIG. 2B, the side surface 22 can be a wave-like surface by that a plurality of grooves 23 having curved corners are sequentially formed so as to be adjacent to one another on the side surface 22. In the side surface 22 thus-formed in a wave-like shape by forming the plurality of the grooves 23 extending along the direction from the second electrode 30 toward the first electrode 10, the adhesion between the protective film 40 and the side surface 22 can be enhanced, and when the protective film 40 is formed on the side surface 22 by a known method, such as sputtering or spin coating, occurrence of disadvantages such as voids can be reduced.

In addition, as shown in FIG. 2B, the depth D₁ of the grooves 23 from the top surface of the side surface 22 may be 20 to 200 nm, and the width W₁ between adjacent grooves 23 may be 20 to 200 nm. The grooves 23 having such a depth D₁ sequentially formed at a density of the width W₁ can enhance the adhesion between the protective film 40 and the side surface 22 without affecting the characteristics, such as piezoelectric properties, of the piezoelectric element.

The piezoelectric element 50 according to the embodiment can have any constitution described above. When the piezoelectric element 50 according to the embodiment is constituted so as to include the substrate 1 as a diaphragm, a piezoelectric actuator 100 including the piezoelectric element 50 can be constituted.

The piezoelectric element according to this embodiment has, for example, the following characteristics.

In the piezoelectric element according to the embodiment, the side surface 22 of the piezoelectric material layer 20 has a plurality of grooves 23 extending along the direction from the second electrode 30 to the first electrode 10, and the protective film 40 is formed on the side surface 22. As a result, since the protective film 40 is also formed in the grooves 23, the area where the protective film 40 adhering to the side surface 22 is increased compared to the case in that the side surface of a piezoelectric material layer 20 is substantially flat. Therefore, a piezoelectric element 50 having enhanced adhesion between the protective film 40 and the side surface 22 of the piezoelectric material layer 20 can be provided.

The piezoelectric element 50 having enhanced adhesion between the protective film 40 and the side surface 22 of the piezoelectric material layer 20 has a constitution in which peeling and cracking hardly occur between the protective film 40 and the side surface 22 even when the piezoelectric element 50 is driven with a relatively high voltage and is continuously vibrated. Therefore, the piezoelectric element 50 according to the embodiment has a constitutionally improved withstand-voltage property. In other words, a piezoelectric element 50 having high reliability can be provided. The details thereof will be described below.

### 1-2. Method of Producing Piezoelectric Element

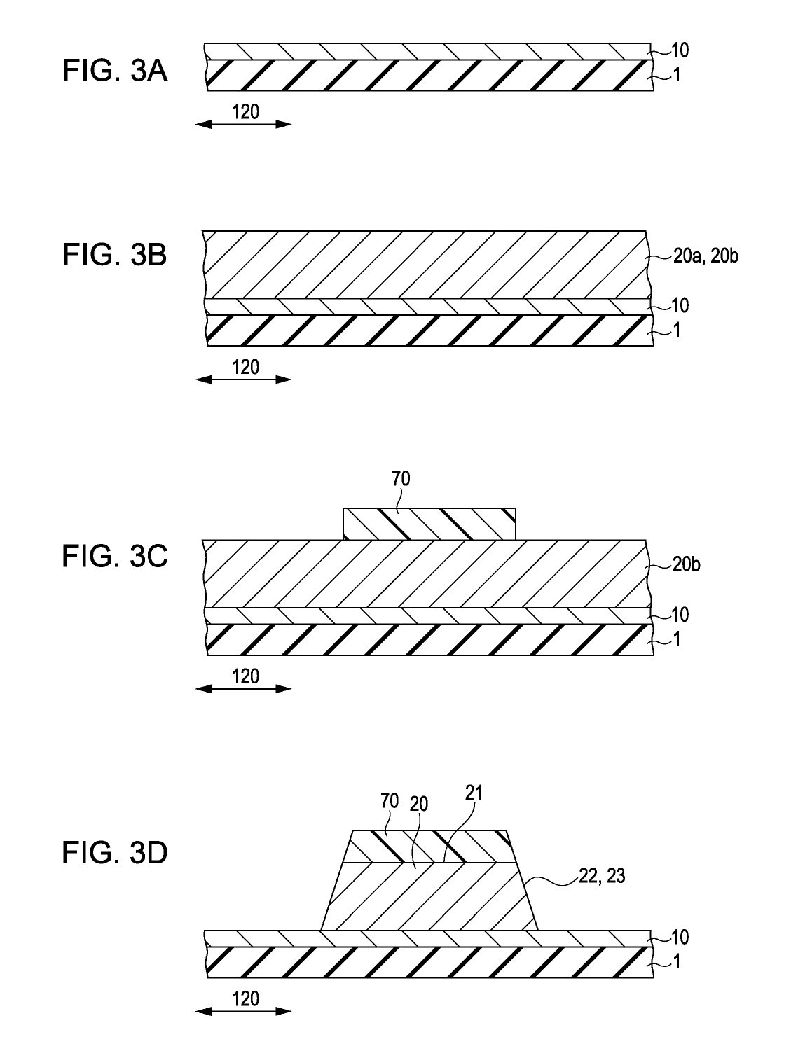

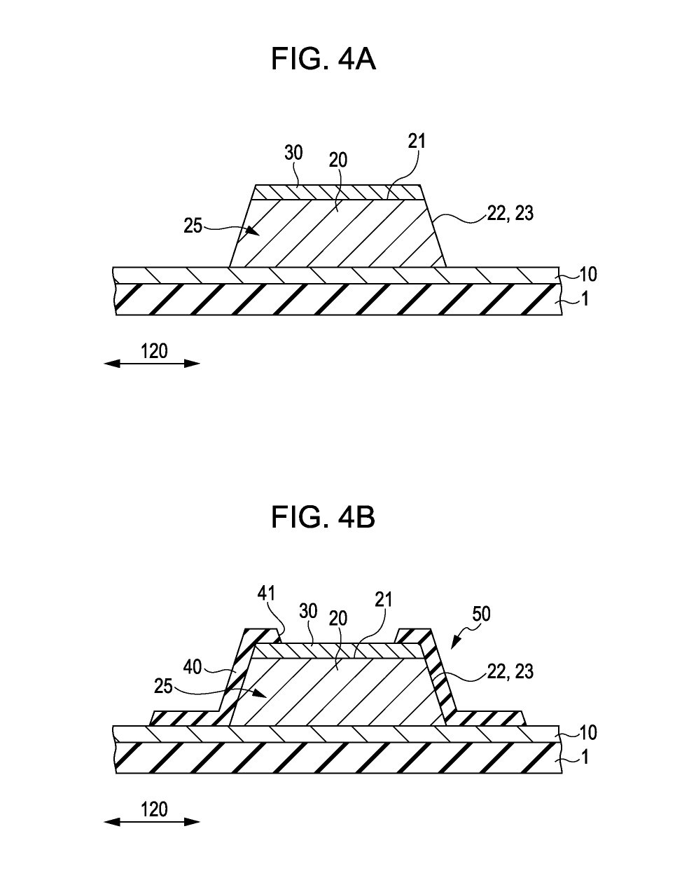

A method of producing the piezoelectric element 50 according to an embodiment will be described below. FIGS. 3A to 3D, 4A, and 4B are cross-sectional views schematically showing a process of producing the piezoelectric element 50 of the embodiment.

The method of producing a piezoelectric element according to the embodiment includes the steps of forming a first electrode 10 on a substrate, forming a piezoelectric material film on the first electrode 10, forming a piezoelectric material layer 20 by patterning the piezoelectric material film by dry etching, forming a second electrode 30 on the piezoelectric material layer 20, and forming a protective film 40 covering at least the side surface 22 of the piezoelectric material layer 20.

First, as shown in FIG. 3A, a first electrode 10 is formed on a substrate 1. The method for forming the first electrode 10 is not particularly limited and can be formed by any known method of forming a film. For example, the first electrode 10 having a desired shape can be formed by forming an electrically conductive film by, for example, vapor deposition such as chemical vapor deposition (CVD) or physical vapor deposition (PVD), plating, sputtering, metal organic deposition (MOD), or spin coating and then patterning the electrically conductive film by a known method. The patterning can be performed by a known photolithography and/or etching. The etching may be either wet etching or dry etching. Alternatively, though it is not shown in the drawings, the patterning may be simultaneously performed when the piezoelectric material layer 20 is patterned.

Here, though it is not shown in the drawings, an oxidation preventing film, such as a titanium nitride film, or an orientation controlling film, such as a titanium film or a lanthanum nickel oxide film, for controlling orientation of the piezoelectric material layer may be formed on the first electrode 10 or on the substrate 1. Furthermore, an adhesion layer made of titanium, chromium, or the like may be disposed between the first electrode 10 and the substrate 1.

Then, as shown in FIG. 3B, a piezoelectric material film 20a is formed on the first electrode 10. The method of forming the piezoelectric material film 20a is not particularly limited and can be formed by any known method of forming a film. For example, the piezoelectric material film 20a can be formed by a sol-gel method or may be formed by, for example, spin coating, CVD, MOD, sputtering, or laser abrasion.

Here, the piezoelectric material film 20a is subjected to heat treatment for crystallizing the piezoelectric material. By doing so, a piezoelectric material film 20b made of a crystallized piezoelectric material can be formed. The conditions for the heat treatment are not particularly limited as long as the treatment is conducted at a temperature that allows crystallization of the piezoelectric material film 20a. For example, the heat treatment can be conducted at a temperature of 500 to 800° C. in an oxygen atmosphere.

Then, the piezoelectric material film 20b is patterned to a desired shape to form the piezoelectric material layer 20. Alternatively, though it is not shown in the drawings, the patterning may be simultaneously performed when the second electrode 30 is patterned. The piezoelectric material film 20b is patterned by known dry etching. The known dry etching may be performed using, for example, an apparatus generating high-density-plasma such as inductively coupled plasma (ICP). The high-density-plasma generating apparatus (dry etching apparatus) can satisfactorily perform etching by setting the pressure to 1.0 Pa or less. Here, as shown in FIG. 3C, a resist 70 for the etching can be appropriately formed. After completion of the etching step, the resist 70 can be properly removed.

The etching gas used for the dry etching can be a gas mixture whose main component is a chlorine-based gas containing BCl₃. The gas mixture can further contain a fluorine-based gas containing C₄F₈ and an argon gas, in addition to the chlorine-base gas containing BCl₃. The mixing ratio of BCl₃ to C₄F₈ in the gas mixture can be in the range of 1 to 4.

In the method of producing the piezoelectric element according to the embodiment, a plurality of grooves 23 can be formed on the side surface 22 of the piezoelectric material layer 20 by forming the piezoelectric material layer 20 by dry etching using the gas mixture. The details thereof will be described below.

As shown in FIG. 4A, a second electrode 30 is formed on the upper surface 21 of the piezoelectric material layer 20. The method of forming the second electrode 30 is not particularly limited and can be formed by forming a second electrically conductive film (not shown) by a known method of forming a film and patterning the film. The second electrically conductive film can be formed by any known method of forming a film.

Then, as shown in FIG. 4B, a protective film 40 is formed so as to cover at least the side surface 22 of the piezoelectric material layer 20. The method of forming the protective film 40 is not particularly limited. For example, when the protective film 40 is formed by a known insulating resin material, the protective film 40 can be formed by forming a resin material film (not shown) by, for example, spin coating and patterning it into a desired shape. Alternatively, for example, when the protective film 40 is formed by a known insulating inorganic material, the protective film 40 can be formed by forming, for example, a metal oxide film (not shown) by, for example, sputtering and patterning it into a desired shape. The patterning can be performed by known photolithography and etching. For example, the protective film 40 having a desired shape may be formed by forming a resist (not shown).

The piezoelectric element 50 can be produced by the above-described process. When the substrate 1 serves as a diaphragm, the above-described process can provide a method of producing a piezoelectric actuator 100.

The method of producing the piezoelectric element 50 or the piezoelectric actuator 100 according to the embodiment has, for example, the following characteristics.

According to the method of producing a piezoelectric element 50 or a piezoelectric actuator 100 of the embodiment, the piezoelectric element 50 or the piezoelectric actuator 100 of the embodiment can be provided.

### 2. LIQUID DROPLET EJECTING HEAD

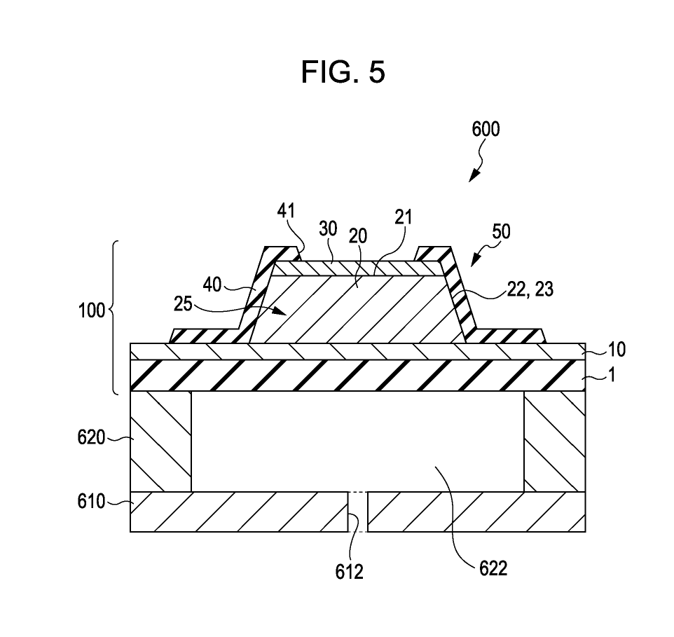

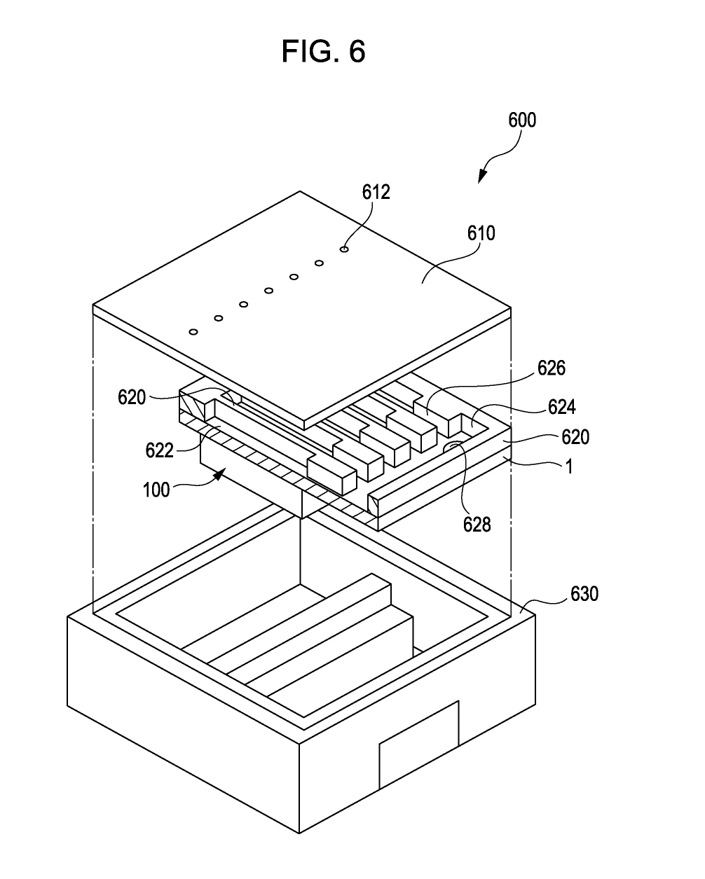

A liquid droplet ejecting head 600 in which the piezoelectric element 50 according to the embodiment functions as the piezoelectric actuator 100 will be described with reference to the drawings. FIG. 5 is a cross-sectional view schematically illustrating the main portion of the liquid droplet ejecting head 600 according to an embodiment. FIG. 6 is an exploded perspective view of the liquid droplet ejecting head 600 according to the embodiment, showing the liquid droplet ejecting head 600 upside down from its usual using state.

The liquid droplet ejecting head 600 can have the above-described piezoelectric element 50 (piezoelectric actuator). In the following example, a liquid droplet ejecting head 600 having the substrate 1 formed as a diaphragm and the piezoelectric element 50 constituted as a piezoelectric actuator will be described.

As shown in FIGS. 5 and 6, the liquid droplet ejecting head 600 includes a nozzle plate 610 having nozzle holes 612, a pressure chamber substrate 620 for forming pressure chambers 622, and the piezoelectric element 50.

The number of the piezoelectric element 50 is not particularly limited. A plurality of the piezoelectric elements 50 may be formed. When a plurality of the piezoelectric elements 50 are formed, the second electrode 30 serves as the common electrode, or the first electrode 10 serves as the common electrode. Furthermore, as shown in FIG. 6, the liquid droplet ejecting head 600 can have a chassis 630. FIG. 6 shows the piezoelectric element 50 in a simplified form.

As shown in FIGS. 5 and 6, the nozzle plate 610 has the nozzle holes 612. From the nozzle holes 612, for example, a liquid (including not only a liquid but also a functional material having an appropriate viscosity adjusted with a solvent or a dispersing medium or a suspension containing, for example, metal flakes, the same shall apply hereinafter), such as an ink, can be discharged as droplets. The nozzle plate 610 is provided with, for example, a large number of nozzle holes 612 aligned in a line. Examples of the material for the nozzle plate 610 include silicon and stainless steel (SUS).

The pressure chamber substrate 620 is disposed on (in the example shown in FIG. 6, under) the nozzle plate 610. Examples of the material for the pressure chamber substrate 620 include silicon. As shown in FIG. 6, a reservoir (liquid reserving portion) 624, feeding apertures 626 communicating with the reservoir 624, and the pressure chambers 622 communicating with the respective feeding apertures 626 are provided by partitioning space between the nozzle plate 610 and the diaphragm 10a by the pressure chamber substrate 620. In this example, the reservoir 624, the feeding apertures 626, and the pressure chambers 622 will be separately described, but each of them is a channel for a liquid or the like and may be designed in any manner. For example, the feeding apertures 626 in the example shown in the drawing each have a shape in which part of the channel is narrowed, but it may be appropriately shaped according to its design, and the structure of the example is not essential. The reservoir 624, the feeding apertures 626, and the pressure chambers 622 are partitioned by the nozzle plate 610, the pressure chamber substrate 620, and the diaphragm 10a. The reservoir 624 can temporally reserve the ink that is supplied from the outside (for example, an ink cartridge) through a via-hole 628 provided in the diaphragm 10a. Ink in the reservoir 624 can be supplied to the pressure chambers 622 through the feeding apertures 626. The volumes of the pressure chambers 622 are changed by deformation of the diaphragm 10a. The pressure chambers 622 are communicated with the nozzle holes 612, and a liquid or the like is discharged from the nozzle holes 612 by the change in the volumes of the pressure chambers 622.

The piezoelectric element 50 is provided on (in the example of FIG. 6, under) the pressure chamber substrate 620. The piezoelectric element 50 is electrically connected to a piezoelectric element driving circuit (not shown) and can be operated (vibrated or deformed) based on the signal of the piezoelectric element driving circuit. The diaphragm 10a is deformed by the movement of the laminate structure (piezoelectric material layer 20) to appropriately change the inner pressures of the pressure chambers 622.

As shown in FIG. 6, the chassis 630 can store the nozzle plate 610, the pressure chamber substrate 620, and the piezoelectric element 50. Examples of the material for the chassis 630 include resins and metals.

The liquid droplet ejecting head 600 includes the piezoelectric element having improved reliability by enhancing the adhesion between the above-described protective film and the side surface of the piezoelectric material layer. Therefore, a liquid droplet ejecting head having improved reliability can be realized.

Here, a case in that the liquid droplet ejecting head 600 is an ink jet recording head has been described. However, the liquid droplet ejecting head of the invention can be also used as, for example, a color material ejecting head used for producing color filters of liquid crystal displays, etc., an electrode material ejecting head used for forming electrodes of organic electroluminescent (EL) displays, field emission displays (FEDs), etc., and a bio-organic matter ejecting head used for producing bio-chips.

### 3. LIQUID DROPLET EJECTING APPARATUS

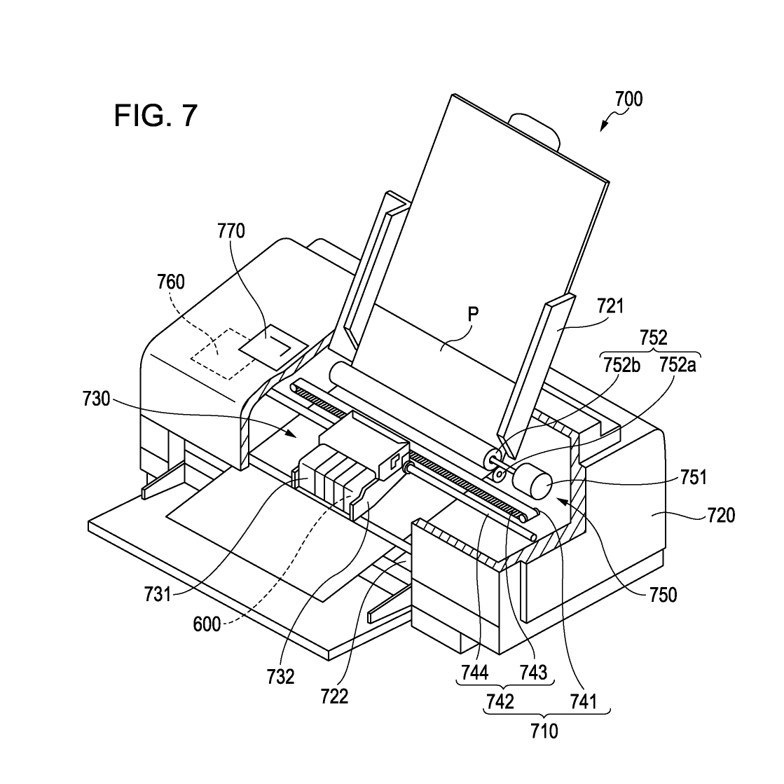

The liquid droplet ejecting apparatus according to an embodiment will be described with reference to the drawings. The liquid droplet ejecting apparatus includes the above-described liquid droplet ejecting head. Hereinafter, an ink jet printer having the above-described liquid droplet ejecting head 600 will be described as the liquid droplet ejecting apparatus. FIG. 7 is a perspective view schematically illustrating the liquid droplet ejecting apparatus 700 according to the embodiment.

As shown in FIG. 7, the liquid droplet ejecting apparatus 700 includes a head unit 730, a driving portion 710, and a controller 760. The liquid droplet ejecting apparatus 700 can further include an apparatus body 720, a paper feeding portion 750, a tray 721 for setting recording paper P, a discharge port 722 for discharging the recording paper P, and an operation panel 770 disposed on the upper surface of the apparatus body 720.

The head unit 730 includes an ink jet recording head (hereinafter, also referred to as simply “head”) constituted of the above-described liquid droplet ejecting head 600. The head unit 730 further includes an ink cartridge 731 supplying ink to the head and a transporting portion (carriage) 732 equipped with the head and the ink cartridge 731.

The driving portion 710 can allow the head unit 730 to reciprocate. The driving portion 710 includes a carriage motor 741 serving as a driving source of the head unit 730 and a reciprocation mechanism 742 for letting the head unit 730 reciprocate with the rotation of the carriage motor 741.

The reciprocation mechanism 742 includes a carriage guide shaft 744 supported by a frame (not shown) at both ends and a timing belt 743 extending parallel to the carriage guide shaft 744. The carriage guide shaft 744 supports the carriage 732 in such a manner that the carriage 732 can freely reciprocate. Furthermore, the carriage 732 is fixed to part of the timing belt 743. The head unit 730 reciprocates along the carriage guide shaft 744 by means of the timing belt 743 that runs by actuation of the carriage motor 741. During this reciprocating movement, ink is appropriately discharged from the head to perform printing on the recording paper P.

In the embodiment, printing is performed while both the liquid droplet ejecting head 600 and the recording paper P are being moved, but the liquid droplet ejecting apparatus of the invention may have a mechanism in which printing on the recording paper P is performed by changing the relative position between the liquid droplet ejecting head 600 and the recording paper P. Furthermore, though the embodiment shows an example in which printing is performed on the recording paper P, the recording medium on which printing is performed by the liquid droplet ejecting apparatus of the invention is not limited to paper, and examples thereof include various media, such as cloth, films, and metals, and the constitution can be appropriately modified.

The controller 760 can control the head unit 730, the driving portion 710, and the paper feeding portion 750.

The paper feeding portion 750 can transport the recording paper P from the tray 721 to the head unit 730 side. The paper feeding portion 750 includes a paper feeding motor 751 serving as a driving source and paper feeding rollers 752 being rotated by actuation of the paper feeding motor 751. The paper feeding rollers 752 are a driven roller 752a and a driving roller 752b that vertically oppose each other with a feeding path of the recording paper P therebetween. The driving roller 752b is connected to the paper feeding motor 751. The paper feeding portion 750 is driven by the controller 760 to transport the recording paper P that passes under the head unit 730.

The head unit 730, the driving portion 710, the controller 760, and the paper feeding portion 750 are disposed inside the apparatus body 720.

The liquid droplet ejecting apparatus 700 includes a piezoelectric element having improved reliability by enhancing the adhesion between the protective film and the side surface of the piezoelectric material layer as described above. Therefore, a liquid droplet ejecting apparatus having improved reliability can be realized.

The liquid droplet ejecting apparatus exemplified above includes one liquid droplet ejecting head and can print on a recording medium with this liquid droplet ejecting head. The liquid droplet ejecting apparatus may have a plurality of the liquid droplet ejecting heads. When the liquid droplet ejecting apparatus has a plurality of the liquid droplet ejecting heads, the liquid droplet ejecting heads may be each independently operated or may be connected to one another as one assembled head. An example of the assembled head is a line-type head in which the nozzle holes of each of the heads are aligned at uniform distances as a whole.

The ink jet recording apparatus 700 as an ink jet printer has been described above as an example of the liquid droplet ejecting apparatus according to the invention, but the liquid droplet ejecting apparatus according to the invention can be also industrially utilized. As the liquid and so on (liquid-like materials) that are discharged in such cases, for example, various functional materials having appropriate viscosities adjusted with solvents or dispersing media can be used. In addition to the image recording apparatus such as a printer, the liquid droplet ejecting apparatus of the invention can be also suitably used as a color material ejecting apparatus used for producing color filters of liquid crystal displays, etc., a liquid material ejecting apparatus used for forming electrodes or color filters of organic EL displays, FEDs, electrophoresis displays, etc., and a bio-organic material ejecting apparatus used for producing bio-chips.

### 4. Example and Comparative Example

An example of the piezoelectric element of the invention and a comparative example of a piezoelectric element will be described below with reference to the drawings.

In the example, a piezoelectric element sample was produced by the piezoelectric element producing method according to the embodiment, and adhesion between the protective film and the piezoelectric material layer and reliability were evaluated. The piezoelectric element for evaluating the characteristics was produced by forming a first electrode 10 containing platinum (Pt) and iridium (Ir) on a substrate so as to have a thickness of 200 nm, forming a piezoelectric material layer 20 consisting of lead zirconate titanate (Pb(Zr,Ti)O₃) on the first electrode 10 so as to have a thickness of 1300 nm, and then forming a second electrode 30 consisting of iridium (Ir) so as to have a thickness of 50 nm. Subsequently, a protective film 40 consisting of aluminum oxide was formed so as to cover the side surface 22 of the piezoelectric material layer 20 and so as to have a thickness of 100 nm. Polarization treatment was performed by applying an electric field of 5 kV/mm for about three minutes in silicon oil.

In the comparative example, a piezoelectric element sample was produced as in the example except that dry etching was performed using a gas mixture of a chlorine gas (Cl₂) and an argon gas (Ar) at a mixture ratio (Cl₂:Ar) of 5:3 instead of the gas mixture whose main component was a chlorine-based gas containing BCl₃.

Adhesion between the protective film and the piezoelectric material layer was evaluated by conducting a withstand voltage test in which voltages ranging from a low voltage (20 V) to a high voltage (80 V) were stepwise applied to the piezoelectric element samples of the example and the comparative example and determining burnout ratios of the samples at each voltage value. Note that the piezoelectric element samples of the example and the comparative example each had 360 segments of the piezoelectric elements on a substrate.

### 4-1. Surface State (SEM Image) of Side Surface of Piezoelectric Material Layer

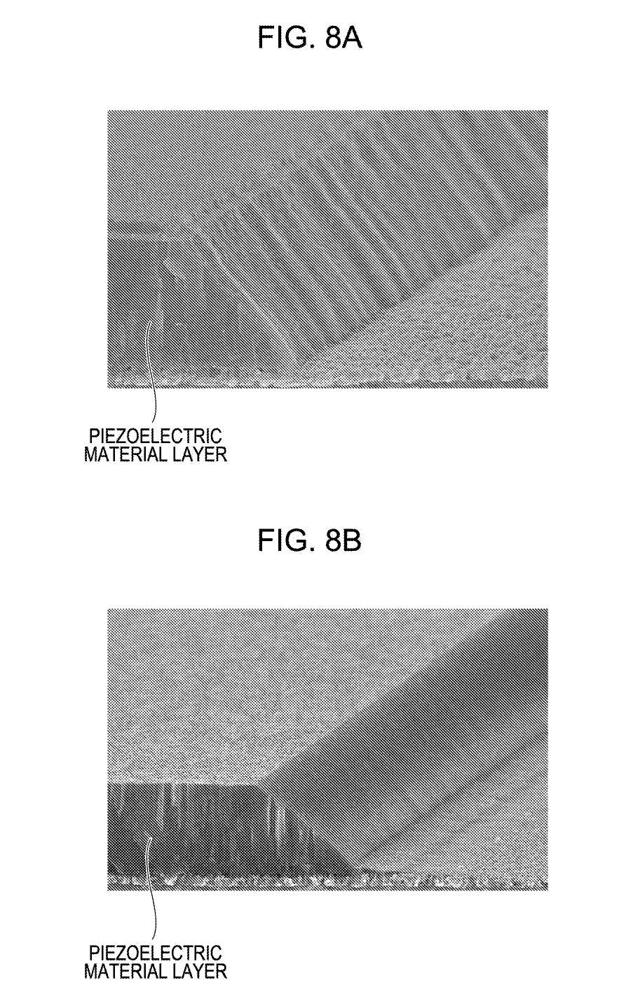

FIG. 8A is an SEM image showing a surface state of the side surface of the piezoelectric material layer of a piezoelectric element sample according to the example, and FIG. 8B is an SEM image showing a surface state of the side surface of the piezoelectric material layer of a piezoelectric element sample according to the comparative example.

As shown in FIG. 8A, it was confirmed that a plurality of grooves extending along the direction from the second electrode toward the first electrode were formed on the side surface of the piezoelectric material layer of the piezoelectric element sample of the example. On the other hand, as shown in FIG. 8B, no grooves were confirmed in the piezoelectric element sample of the comparative example, unlike in the example, and it was confirmed that the side surface was substantially flat.

Thus, it was confirmed that in the method of producing a piezoelectric element according to an aspect of the invention, a plurality of grooves can be efficiently formed on the side surface of the piezoelectric material layer.

### 4-2. Withstand Voltage Test

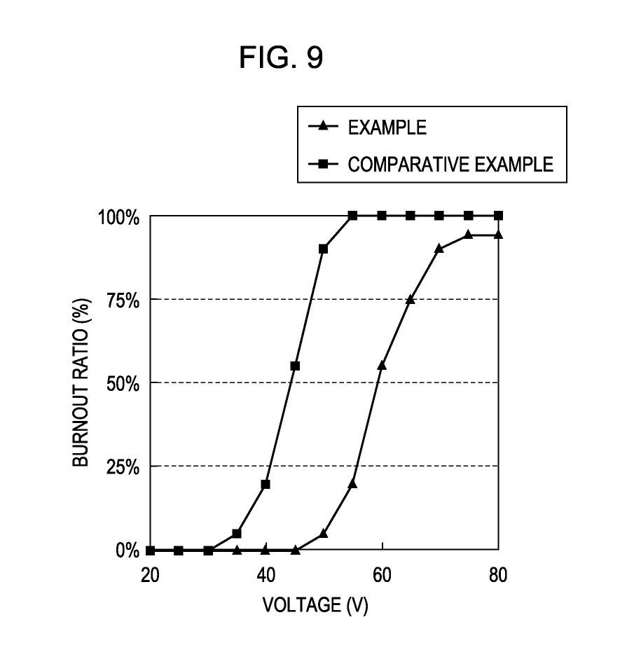

FIG. 9 is a graph showing the results of a withstand voltage test of the piezoelectric element samples of the example and the comparative example. Applied voltages (V) are plotted on the horizontal axis, and burnout ratios of the samples at each voltage value are plotted on the vertical axis. Here, the term “burnout ratio” refers to the proportion of the sample burnt out by, for example, short circuit due to current leakage that is caused by cracking or peeling between the protective film and the side surface of the piezoelectric material layer. That is, a larger burnout ratio means that peeling or cracking readily occurs between the protective film and the side surface of the piezoelectric material layer.

The application of voltage was set so that voltages were stepwise (5 V each time) increased from 20 V to 80 V, and the burnout ratios of the samples of the example and the comparative example at each voltage were confirmed.

As shown in FIG. 9, in the sample of the comparative example, burnout segments were confirmed when the applied voltage was 35 V. However, in the sample of the example, no burnout segments were confirmed until a voltage of 50 V was applied. Since when a voltage of 50 V was applied, about 90% of the segments were burnt out in the sample of the comparative example, it was confirmed that the constitutional withstand-voltage property of the sample of the example was significantly improved by an enhancement in adhesion between the protective film and the side surface of the piezoelectric material layer.

Thus, it was confirmed that in the constitution of the piezoelectric element according to the embodiment, since peeling and cracking hardly occur between the protective film and the side surface of the piezoelectric material layer because of the enhancement in adhesion between the protective film and the side surface of the piezoelectric material layer, the withstand voltage property is increased to provide high reliability.

As described above, in the piezoelectric element and the method of producing a piezoelectric element according to aspects of the invention, a piezoelectric element having improved adhesion between the protective film and the piezoelectric material layer can be provided.

Note that the above-described embodiments and various modifications thereof are only exemplified examples, and the invention is not limited thereto. For example, it is possible to appropriately combine two or more of the embodiments and various modifications thereof.

The invention is not limited to the above-described embodiments, and it is possible to further make various modifications. For example, the invention includes constitutions substantially the same as those described in the embodiments (for example, a constitution that is the same in the function, method, and results or a constitution that is the same in the purpose and effect). Furthermore, the invention includes constitutions in which unessential portions of the constitutions described in the embodiments are substituted. The invention includes constitutions that can achieve the same effect or the same purpose as those of the constitutions described in the embodiments. Furthermore, the invention includes constitutions in which known technology is added to the constitutions described in the embodiments.

1. A piezoelectric element comprising:
a first electrode disposed on a substrate;
a piezoelectric material layer disposed on the first electrode;
a second electrode disposed on the piezoelectric material layer; and
a protective film covering at least a side surface of the piezoelectric material layer,
wherein the side surface of the piezoelectric material layer has a plurality of grooves extending along the direction from the second electrode toward the first electrode.

2. The piezoelectric element according to claim 1, wherein the grooves on the side surface each have a depth of 20 to 200 nm.

3. The piezoelectric element according to claim 1, wherein the material for the protective film is an insulating resin material and/or an insulating inorganic material.

4. A piezoelectric actuator comprising the piezoelectric element according to claim 1.

5. A liquid droplet ejecting head comprising the piezoelectric actuator according to claim 4.

6. A liquid droplet ejecting apparatus comprising the liquid droplet ejecting head according to claim 5.

7. A method of producing a piezoelectric element comprising:
forming a first electrode on a substrate;
forming a piezoelectric material film on the first electrode;
forming a piezoelectric material layer by patterning the piezoelectric material film by dry etching;
forming a second electrode on the piezoelectric material layer; and
forming a protective film covering at least a side surface of the piezoelectric material layer,
wherein the etching gas in the dry etching is a gas mixture whose main component is a chlorine-based gas containing BCl₃.

8. The method of producing a piezoelectric element according to claim 7, wherein
the gas mixture contains at least BCl₃ and C₄F₈ with a mixing ratio of BCl₃ to C₄F₈ in the range of 1 to 4.

9. The method of producing a piezoelectric element according to claim 7, wherein
the dry etching is performed under a pressure of 1.0 Pa or less.
